(19) United States
(12) Patent Application Publication
(10) Pub. No.: US 2005/0139888 A1
(43) Pub. Date: Jun. 30, 2005

(54) Semiconductor device and fabricating method thereof

(75) Inventor: Tae Woo Kim, Icheon (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/027,852

(22) Filed: Dec. 29, 2004

(30) Foreign Application Priority Data
Dec. 31, 2003 (KR) 10-2003-0101538

(51) Int. Cl. H01L 21/8234; H01L 21/8244; H01L 27/108; H01L 29/76; H01L 29/94; H01L 31/119; H01L 21/20

(52) U.S. Cl. 257/296; 438/238

(57) ABSTRACT

A semiconductor device and fabricating method thereof is provided, by which capacitance is enhanced by increasing an effective area of a lower electrode of a capacitor. A lower electrode is included on a semiconductor substrate, a plurality of conductive protrusions having a cup or U shape is formed on the lower electrode, a dielectric layer covers the lower electrode and a plurality of the conductive protrusions, and an upper electrode is formed on the dielectric layer.

This application claims the benefit of the Korean Application No. P2003-0101538 filed on Dec. 31, 2003, which is hereby incorporated by reference.

### BACKGROUND OF THE INVENTION

1. Field of the Invention

The present invention relates to a semiconductor device and fabricating method thereof, and more particularly, to a capacitor and a fabricating method thereof, by which capacitance is enhanced by increasing an effective area of a lower electrode of the capacitor.

2. Discussion of the Related Art

Generally, in a unit cell configured with a MOS transistor and a capacitor, device characteristics are considerably affected by capacitance of the capacitor. As a capacitor occupying area is reduced according to a highly increasing degree of semiconductor device integration, large capacitance of a capacitor is badly needed more than ever.

To increase capacitance of a capacitor, there are various methods such as a method of increasing an effective area of a capacitor, a method of thinning a dielectric layer between upper and lower electrodes, a method of forming a dielectric layer of a high dielectric constant, and the like.

Yet, the method of thinning a dielectric layer lowers reliability of a semiconductor device. And, the method of forming a dielectric layer of a high dielectric constant needs to develop a new capacitor fabricating process.

Hence, many efforts are made to develop the method of increasing an effective area.

FIG. 1 is a cross-sectional diagram of a capacitor in a semiconductor device according to a related art.

Referring to FIG. 1, a lower electrode 102, a dielectric layer 104, and an upper electrode 105 are sequentially stacked on a semiconductor substrate 101 to configure a capacitor embedded in an insulating interlayer 103.

In such a capacitor structure of the related art, since the lower electrode 102 has a planar shape, an area of the lower electrode 102 is decreased according to a reduced design rule of semiconductor device.

Hence, a structural limitation is put on the related art capacitor in maximizing capacitance in a microscopic device.

### SUMMARY OF THE INVENTION

Accordingly, the present invention is directed to a semiconductor device and fabricating method thereof that substantially obviates one or more problems due to limitations and disadvantages of the related art.

An object of the present invention is to provide a semiconductor device and fabricating method thereof, by which capacitance is enhanced by increasing an effective area of a lower electrode of a capacitor.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a semiconductor device according to the present invention includes a lower electrode on a semiconductor substrate, a plurality of conductive protrusions on the lower electrode having a cup shape or a cross-section having a substantial U shape, a dielectric layer covering the lower electrode and the plurality of conductive protrusions, and an upper electrode on the dielectric layer.

Preferably, the lower electrode has a thickness of from 1,000 to about 1,500 Å.

Preferably, each of the plurality of conductive protrusions has a thickness of from about 1,000 to about 1,500 Å.

In another aspect of the present invention, a method of fabricating a semiconductor device includes the steps of forming a planar lower electrode on a substrate, forming a plurality of conductive protrusions on the lower electrode to configure a plurality of cup shapes, respectively, forming a dielectric layer covering the lower electrode and a plurality of the conductive protrusions, and forming an upper electrode on the dielectric layer.

Preferably, the conductive protrusion forming step includes the steps of forming a first sacrificial layer on the substrate including the lower electrode, forming a plurality of openings in the first sacrificial layer to expose a surface of the lower electrode, forming a metal layer on the first sacrificial layer including inside the plurality of openings, forming a second sacrificial layer on the metal layer, planarizing the second sacrificial layer and the metal layer until the first sacrificial layer is exposed, and removing the remaining second and first sacrificial layers.

More preferably, the metal layer is formed to leave a prescribed space in each of the plurality of openings.

Preferably, the lower electrode has a thickness of from 1,000 to about 1,500 Å.

Preferably, each of the plurality of conductive protrusions has a thickness of from 1,000 to about 1,500 Å.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional diagram of a capacitor in a semiconductor device according to a related art;

FIG. 2 is a cross-sectional diagram of a capacitor in a semiconductor device according to the present invention; and

FIGS. 3A to 3D are cross-sectional diagrams for explaining a method of fabricating a capacitor in a semiconductor device according to the present invention.

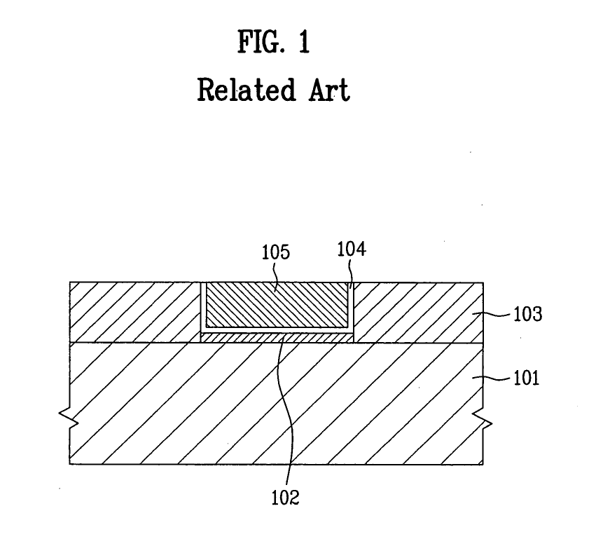

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

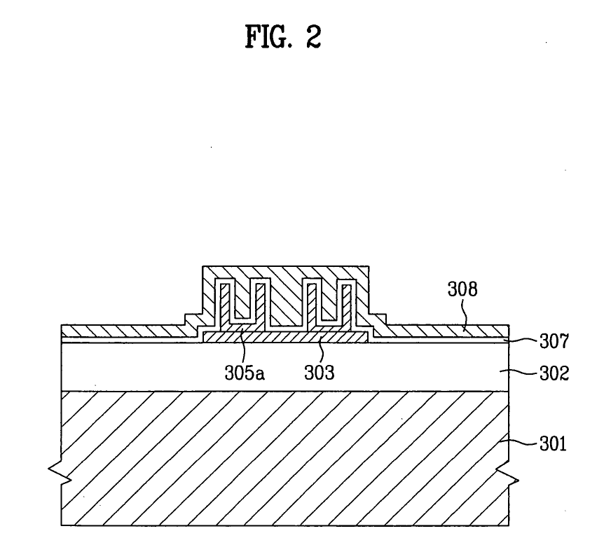

FIG. 2 is a cross-sectional diagram of a capacitor in a semiconductor device according to the present invention.

Referring to FIG. 2, a capacitor according to the present invention includes a lower electrode 303 having an uneven part 305a on a semiconductor substrate 301, a dielectric layer 307 on the lower electrode 303, and an upper electrode 308 on the dielectric layer 307.

Specifically, the lower electrode 303 includes a first lower electrode 303 having a planar shape and a second lower electrode 305a on the first lower electrode 303 to have a plurality of cup type protrusions leaving a prescribed interval from each other. Alternatively and/or additionally, each of the second lower electrodes 305a may have a substantially U-shaped cross-section, as shown in the Figures.

Hence, capacitance of the capacitor of the resent invention is increased since an effective area of the lower electrode 303 contacting with the dielectric layer 307 is increased due to the second lower electrode 305a.

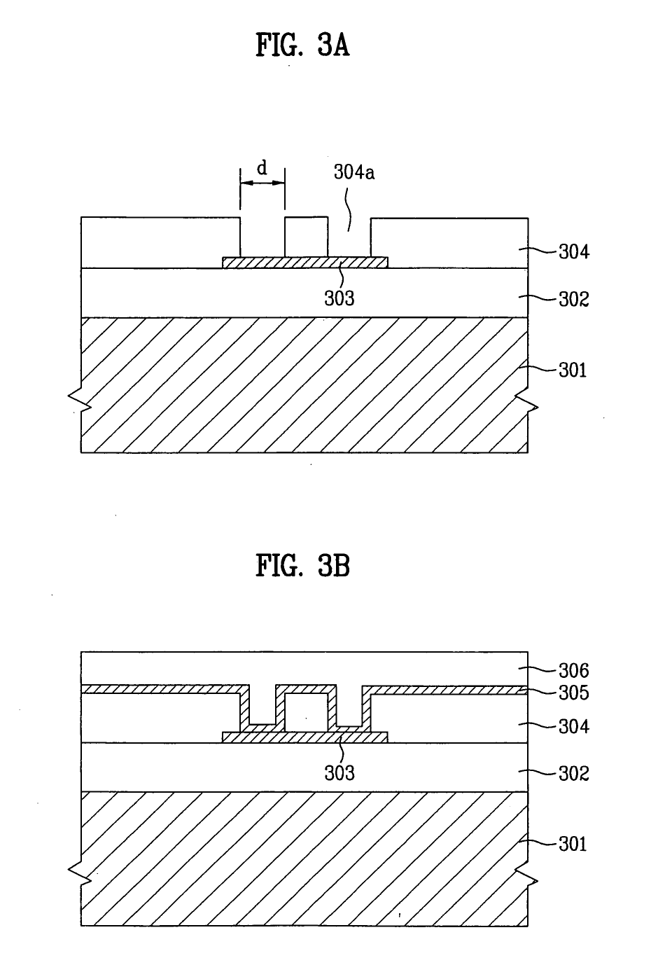

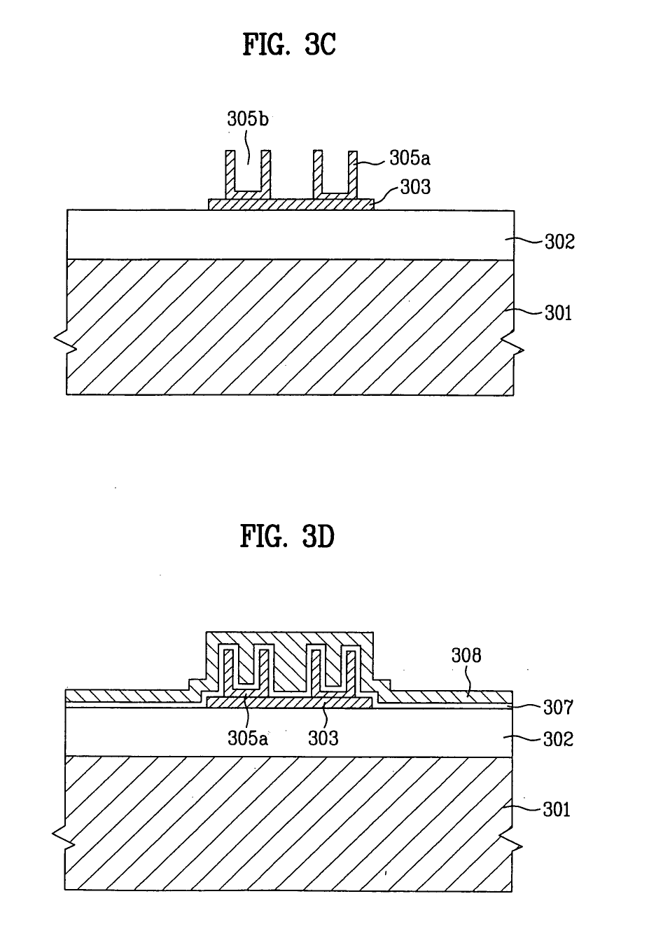

FIGS. 3A to 3D are cross-sectional diagrams for explaining a method of fabricating a capacitor in a semiconductor device according to the present invention.

Referring to FIG. 3A, an insulating interlayer is deposited on a semiconductor substrate 301. In doing so, the insulating interlayer 302 is formed of a general oxide layer such as a BPSG (borophosphroussilicate glass) layer and the like. Besides, a device (not shown in the drawing) such as a MOS transistor and the like is formed on an active area of the substrate 301 under the insulating interlayer 302.

A first metal layer is deposited (e.g., about 1,000˜1,500 Å thick) on the insulating interlayer 302. The first metal layer is patterned by photolithography to form a first lower electrode 303. In doing so, the metal layer for forming the first lower electrode 303 is preferably formed of Al—Cu. Alternatively, the first lower electrode 303 can be formed of a metal, which has a high work function and low reactivity with a dielectric layer 307 formed thereon, such as Pt, Ru, Ir, Rh, Os, and the like.

A first sacrificial oxide layer 304 is then deposited over the substrate 301 including the first lower electrode 303.

Subsequently, the first sacrificial oxide layer 304 is selectively etched by photolithography to form a plurality of openings 304a exposing a surface of the first lower electrode 303. In ding so, each of the openings 304a has a prescribed width d.

Referring to FIG. 3B, a second metal layer 305 is deposited (e.g., about 1,000˜1,500 Å thick) over the substrate 301 including the insides of a plurality of the openings. In doing so, the second metal layer 305 may comprise W and be deposited by chemical vapor deposition (CVD).

A second sacrificial oxide layer 304 is then deposited on the second metal layer 305 to fill up a plurality of the openings. The second sacrificial oxide layer 306 will play a role as a buffer layer in performing CMP (chemical mechanical polishing) later.

Referring to FIG. 3C, the second sacrificial oxide layer and the second metal layer are planarized to expose the first sacrificial oxide layer 304. Hence, the second metal layer remains in a plurality of the openings.

Subsequently, the remaining second sacrificial oxide layer and the remaining first sacrificial oxide layer are removed by wet or dry etch.

Hence, a second lower electrode 305a including a plurality of the cup type protrusions 305b is formed on the first lower electrode 303 to complete a lower electrode including the first lower electrode 303 and the second lower electrode 305a.

Referring to FIG. 3D, a dielectric layer 307 is deposited on the insulating interlayer 302 including the lower electrode. In doing so, the dielectric layer 307 is formed of a material having a high dielectric constant. For example, the dielectric layer 307 can be formed 400˜600 Å thick and can comprise a nitride layer (e.g., silicon nitride).

A third metal layer 308 is formed on the dielectric layer 307. The third metal layer is then selectively patterned to remain on a specific area including the dielectric layer 307, thereby forming an upper electrode (not shown in the drawing).

As mentioned in the foregoing description, the lower electrode of the present invention further includes the cup type protrusions to increase the contact areas of the upper and lower electrodes contacting with the dielectric layer each. Hence, an effective area of the capacitor of the present invention is considerably larger than that of the related art.

Accordingly, in the present invention, the cup type protrusions are provided to the lower electrode to increase the effective area of the capacitor, whereby capacitance of the capacitor is maximized.

It will be apparent to those skilled in the art that various modifications and variations can be made in the present invention. Thus, it is intended that the present invention covers the modifications and variations of this invention provided they come within the scope of the appended claims and their equivalents.

1. A semiconductor device comprising:
a lower electrode on a semiconductor substrate;
a plurality of conductive protrusions on the lower electrode, each of the plurality of conductive protrusions having a cup shape or a cross-section with a substantial U shape;
a dielectric layer covering the lower electrode and the plurality of the conductive protrusions; and
an upper electrode on the dielectric layer.

2. The semiconductor device of claim 1, wherein the lower electrode has a thickness of from about 1,000 to about 1,500 Å.

3. The semiconductor device of claim 1, wherein each of the plurality of conductive protrusions has a thickness of from about 1,000 to about 1,500 Å.

4. A method of fabricating a semiconductor device, comprising the steps of:
forming a planar lower electrode on a substrate;
forming a plurality of conductive protrusions on the lower electrode, each of the plurality of conductive protrusions having a cup shape or a cross-section with a substantial U shape;
forming a dielectric layer covering the lower electrode and the plurality of the conductive protrusions; and
forming an upper electrode on the dielectric layer.

5. The method of claim 4, the conductive protrusion forming step comprising the steps of:
forming a first sacrificial layer on the substrate including the lower electrode;
forming a plurality of openings in the first sacrificial layer to expose a surface of the lower electrode;
forming a metal layer on the first sacrificial layer including inside the plurality of openings;
forming a second sacrificial layer on the metal layer;
planarizing the second sacrificial layer and the metal layer until the first sacrificial layer is exposed; and
removing the remaining second and first sacrificial layers.

6. The method of claim 5, wherein forming the metal layer leaves a prescribed space in each of the plurality of openings.

7. The method of claim 4, wherein the lower electrode has a thickness of from 1,000 to about 1,500 Å.

8. The method of claim 4, wherein each of the plurality of conductive protrusions has a thickness of from 1,000 to about 1,500 Å.
